(19) United States
(12) Patent Application Publication
(10) Pub. No.: US 2007/0230530 A1
(43) Pub. Date: Oct. 4, 2007

(54) SEMICONDUCTOR LASER DEVICE AND METHOD FOR MANUFACTURING THE SAME

(75) Inventors: Takayuki KASHIMA, Okayama (JP); Kuoji MAKITA, Hyogo (JP); Kenji YOSHIKAWA, Okayama (JP)

Correspondence Address: HAMRE, SCHUMANN, MUELLER & LARSON P.C., P.O. BOX 2902-0902, MINNEAPOLIS, MN, 55402, US

(73) Assignee: MATSUSHITA ELECTRIC INDUSTRIAL CO., LTD., Osaka (JP)

(21) Appl. No.: 11/567,396

(22) Filed: Dec. 6, 2006

(30) Foreign Application Priority Data
Dec. 7, 2005 (JP) JP2005-354050

(51) Int. Cl. H01S 5/00

(52) U.S. Cl. 372/46.01; 372/50.1

(57) ABSTRACT

A semiconductor laser device including the following: a first conductivity type semiconductor substrate; a first conductivity type cladding layer disposed on the semiconductor substrate; an active layer disposed on the first conductivity type cladding layer; a second conductivity type first cladding layer disposed on the active layer; a second conductivity type second cladding layer that is disposed on the second conductivity type first cladding layer and forms a ridge waveguide extending in a resonator direction; a second conductivity type contact layer disposed on the second conductivity type second cladding layer; and an end face window structure in which impurities are diffused into an active layer region of an end face portion in the resonator direction. Thus a band gap is enlarged compared to a gain region that is a portion other than the end face portion. In the second conductivity type first and second cladding layers, an impurity concentration in the gain region is the same as or larger than that in a region of the end face window structure. This configuration can form an end face window structure with a smaller refractive index variation, achieve a higher resistance than a conventional window structure, and control Zn diffusion in the resonator direction.

### BACKGROUND OF THE INVENTION

1. Field of the Invention

The present invention relates to a semiconductor laser device having an end face window structure and a method for manufacturing the semiconductor laser device.

2. Description of Related Art

In recent years, a DVD drive for recording/reproducing optical information characterized by a large storage capacity has been widespread rapidly in various fields including video players. On the other hand, with an increase in applications of high-speed writing, a further improvement in optical output has been required for a semiconductor laser device that is used as a light source.

To ensure stability and reliability for a high output operation, a real refractive index guided structure generally is used and a laser end face portion is formed to be a window structure having a larger band gap than the radiated laser beam. This can suppress deterioration of the laser due to heat generated from the interface state between the end face coating film and the end face of the laser.

In recent years, the formation of the end face window structure has been an important aspect to ensure a high output operation for a laser device. As a method for producing the end face window structure, JP 2001-210907 A discloses a general technique. A method for producing the end face window structure of a red laser device according to the conventional technique will be described with reference to FIGS. 4A to 4C by taking the method of JP 2001-210907 A as an example.

As shown in FIG. 4A, an n-type GaAs buffer layer 22, an n-type AlGaInP cladding layer 23, an active layer (having a multiple quantum well structure with an oscillation wavelength of 650 nm) 24, a p-type AlGaInP first cladding layer 25, a GaInP etching stop layer 26, a p-type AlGaInP second cladding layer 27, a p-type GaInP intermediate layer 28, and a p-type GaAs contact layer 29 are formed in this order on an n-type GaAs substrate 21 by metal organic vapor phase epitaxy (referred to as MOVPE method in the following).

Next, a ZnO layer is deposited on the entire surface of the wafer by using a deposition apparatus such as a sputtering apparatus (not shown). As shown in FIG. 4B, patterning is performed with a photoresist so that the ZnO layer 30 remains only in a region where the window structure is to be formed. Then, an insulating film 31 is deposited on the entire surface of the wafer, and solid phase diffusion of Zn from the ZnO layer 30 is caused with an appropriate temperature and time for diffusing Zn into the crystal. Therefore, in the region where Zn is diffused, the active layer 24 that has been formed by crystal growth is disordered, and an end face window structure region 32 having a larger band gap than the active layer 24 is formed, as shown in FIG. 4C.

In this case, the p-type GaAs contact layer 29 on the region where the window structure is formed functions as a Zn diffusion controlling layer and thus allows the window structure to be formed stably in the end face portion. Suppressing excess diffusion of Zn also makes it possible to suppress erosion of the GaInP etching stop layer 26 in the subsequent process of forming a stripe, so that the same stripe shape as in the gain portion can be obtained.

However, the above structure for hither output of the laser beam poses the following problems.

(1) Expansion of the Zn diffusion in the resonator direction of the active layer portion

This results in significant losses and poor reliability because of increases in a threshold value and an operation current or the generation of regions with a small band gap difference.

(2) Low resistance caused by high-concentration Zn diffusion Since the Zn concentration is higher than the laser gain region, a current flows easily into the end face portion during current injection, which leads to heat generation. Thus, the band gap becomes smaller, and end face damage is likely to occur.

(3) Refractive index change by high-concentration Zn

As a result of Zn diffusion into the end face portion, light scattering occurs due to a refractive index variation in the cladding layers. This may cause a difference in the divergence angle of a laser between the gain portion and the exit end face or a light loss.

JP 2004-259943 A or JP 2001-94206 A addresses these problems. JP 2004-259943 A discloses that an end face window structure can be formed by doping the second conductivity type layer with As atoms when the window structure is formed, while suppressing the diffusion of impurities into the active layer of the gain region, as indicated by the problem (1).

JP 2001-94206 A discloses that an end face window structure can be formed based on the effect of extruding Si by annealing after n-type GaAs is grown selectively on p-type GaAs in the end face portion. This solves the problem (1) as well as the problem (2) of a low resistance because Si is diffused into the p-type layer of the end face portion.

However, even if both the methods of JP 2004-259943 A and JP 2001-94206 A are used, it is difficult to avoid the problem (3) of a refractive index difference between the gain portion and the end face window structure region. In particular, diffusion of the impurities with a conductivity type different from the gain portion into the end face portion may cause the divergence angle to behave differently from the window structure formed by conventional Zn diffusion or may result in characteristic variations.

### SUMMARY OF THE INVENTION

Therefore, with the foregoing in mind, it is an object of the present invention to provide a semiconductor laser device that has an end face window structure in which a refractive index difference between the gain portion and the end face window structure region is suppressed, and that can achieve stable device characteristics and high reliability even in a high output operation.

It is also an object of the present invention to provide a method for manufacturing a semiconductor laser device that can form an end face window structure with a smaller refractive index variation, suppress a reduction in resistance, and control Zn diffusion in the resonator direction.

A semiconductor laser device of the present invention includes the following: a first conductivity type semiconductor substrate; a first conductivity type cladding layer that is disposed on the semiconductor substrate; an active layer that is disposed on the first conductivity type cladding layer and has a multiple quantum well structure; a second conductivity type first cladding layer that is disposed on the active layer; a second conductivity type second cladding layer that is disposed on the second conductivity type first cladding layer and forms a ridge waveguide extending in a resonator direction; a second conductivity type contact layer that is disposed on the second conductivity type second cladding layer; and an end face window structure in which impurities are diffused into an active layer region of an end face portion in the resonator direction. Thus, a band gap is enlarged compared to a gain region that is a portion other than the end face portion. In the second conductivity type first and second cladding layers, the impurity concentration in the gain region is the same as or larger than that in a region of the end face window structure.

A method for manufacturing a semiconductor laser device of the present invention includes the following: performing crystal growth of a first conductivity type cladding layer, an active layer, a second conductivity type first cladding layer, a second conductivity type second cladding layer, and a second conductivity type contact layer in this order on a semiconductor substrate; depositing a source of diffusion force that includes no second conductivity type impurity on only an end face portion in a resonator direction; performing annealing so as to cause a stress generated by the source of diffusion force to be applied to the layers, allowing impurities inside the layers to be diffused to form an end face window structure; forming the second conductivity type second cladding layer into a ridge waveguide extending in the resonator direction; removing the second conductivity type contact layer in a region of the end face window structure; and forming a first conductivity type blocking layer on sides of the second conductivity type second cladding layer in the form of a ridge waveguide and also regions on both sides of the second cladding layer.

### BRIEF DESCRIPTION OF THE DRAWINGS

FIG. 1A is a perspective view of a semiconductor laser device of an embodiment of the present invention.

FIG. 1B is a cross-sectional view taken along the line A-A′ in FIG. 1A.

FIG. 1C is a cross-sectional view taken along the line B-B′ in FIG. 1A.

FIG. 2A is a perspective view showing a manufacturing process of the semiconductor laser device.

FIG. 2B is a perspective view showing a manufacturing process of the semiconductor laser device after FIG. 2A.

FIG. 2C is a perspective view showing a manufacturing process of the semiconductor laser device after FIG. 2B.

FIG. 2D is a perspective view showing a manufacturing process of the semiconductor laser device after FIG. 2C.

FIG. 3 shows a SIMS profile of Zn in the semiconductor laser device.

FIG. 4A is a perspective view showing a manufacturing process of a conventional semiconductor laser device.

FIG. 4B is a perspective view showing a manufacturing process of the conventional semiconductor laser device after FIG. 4A.

FIG. 4C is a perspective view showing a manufacturing process of the conventional semiconductor laser device after FIG. 4B.

### DETAILED DESCRIPTION OF THE INVENTION

A semiconductor laser device of the present invention includes a laminated structure of a first conductivity type cladding layer, an active layer having a multiple quantum well structure, and a second conductivity type first cladding layer, a second conductivity type second cladding layer that forms a ridge waveguide, and a second conductivity type contact layer disposed on the second cladding layer. The semiconductor laser device also has an end face window structure in which impurities are diffused into an active layer region of an end face portion in a resonator direction, and thus a band gap is enlarged compared to a gain region that is a portion other than the end face portion. In the second conductivity type first and second cladding layer, the impurity concentration in the gain region is adjusted to be the same as or larger than that in a region of the end face window structure. With this configuration, there is a small difference in refractive index between the gain portion and the end face window structure region. Therefore, it is possible to obtain not only the laser characteristics that reduce a divergence angle variation and losses, but also the device characteristics that are stable even in a high output operation.

In the semiconductor laser device with the above configuration of the present invention, it is preferable that carriers in the second conductivity type first and second cladding layers and impurities in the end face window structure are the same element.

The carriers in the second conductivity first and second cladding layers may be Zn or Mg.

It is preferable that the carrier concentration in each of the second conductivity type layers in the gain region is set to satisfy the relationship of (concentration in the contact layer)≧(concentration in the second cladding layer)≧(concentration in the first cladding layer).

It is preferable that the second conductivity type contact layer is formed of a single layer film or multilayer film with a carrier concentration of 8×10¹⁸ to 6×10¹⁹ cm⁻³.

It is preferable that the second conductivity type second cladding layer has a carrier concentration of 1.5×10¹⁸ cm⁻³ or less.

It is preferable that the second conductivity type first cladding layer has a carrier concentration of 1×10¹⁸ cm⁻³ or less.

It is preferable that second conductivity type impurities are piled up in a concentration of 1×10¹⁸ to 5×10¹⁸ cm⁻³ in the active layer of the end face window structure region.

It is preferable that second conductivity type impurities are diffused into the first conductivity type cladding layer in the end face window structure region.

It is preferable that a depth of diffusion of the impurities into the first conductivity type cladding layer in the end face window structure region is within 2 μm.

A method for manufacturing a semiconductor laser device of the present invention includes, after forming a laminated structure that constitutes a resonator on a semiconductor substrate, processes of depositing a source of diffusion force that includes no second conductivity type impurity on only the end face portion in the resonator direction and performing annealing so as to cause a stress generated by the source of diffusion force to be applied to the layers, allowing impurities inside the layers to be diffused to form an end face window structure. With this manufacturing method, the carriers inside the laser are diffused into the active layer for disordering without using a layer that contains the second conductivity type impurities as a source of diffusion force, so that a large amount of carriers is not diffused into the end face portion. Therefore, a low resistance of the end face portion can be avoided, and the end face window structure can be reduced in both refractive index variation and Zn diffusion in the resonator direction. Thus, it is possible to obtain the laser characteristics that reduce a divergence angle variation and losses, and also to ensure reliability in a high output operation.

In the manufacturing method for the semiconductor laser device with the above configuration of the present invention, the formation of the end face window structure by impurity diffusion in the end face portion may be performed by extruding the impurities present in the second conductivity type second cladding layer and the second conductivity type contact layer from above so that the impurities are diffused into the active layer.

The source of diffusion force formed in the end face portion may be a single layer or multilayer film selected from any of Si, SiN, SiO₂, TiO₂, Ta₂O₅, NbO, and hydrogenated amorphous Si.

It is preferable that the diffusion concentration of impurities diffused by action of the source of diffusion force is 1×10¹⁷ cm⁻³ or more.

It is preferable that the formation of the end face window structure by impurity diffusion in the end face portion is performed at an annealing temperature of 400 to 800° C.

It is preferable that the formation of the end face window structure by impurity diffusion in the end face portion is performed so that the impurity diffusion in the resonator direction is controlled within 15 μm with respect to the width of the source of diffusion force.

Hereinafter, an embodiment of the present invention will be described with reference to the drawings.

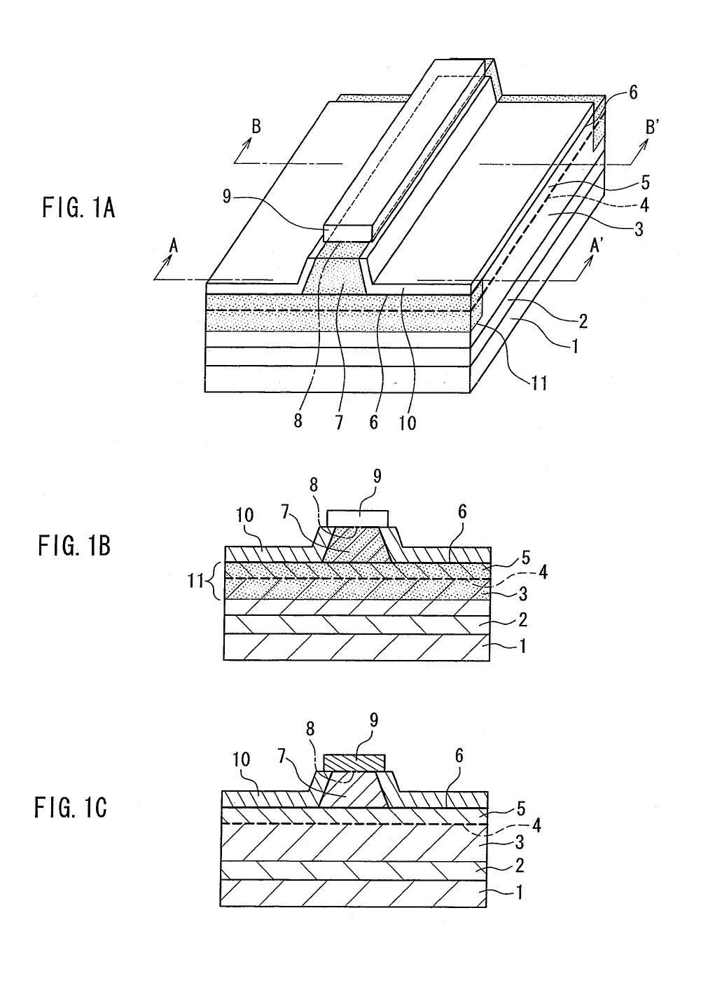

FIG. 1A is a perspective view showing the structure of a semiconductor laser device of an embodiment of the present invention. FIG. 1B is a cross-sectional view taken along the line A-A′ in FIG. 1A. FIG. 1C is a cross-sectional view taken along the line B-B′ in FIG. 1A.

As shown in FIGS. 1A and 1B, this semiconductor laser includes an n-type GaAs OFF substrate 1 and an n-type GaAs buffer layer 2, an n-type (AlₓGa₁₋ₓ)_{y}In_{1-y}P cladding layer 3, an active layer 4 made of a GaInP material, a p-type (AlₓGa₁₋ₓ)_{y}In_{1-y}P first cladding layer 5, a GaInP etching stop layer 6, a p-type (AlₓGa₁₋ₓ)_{y}In_{1-y}P second cladding layer 7 in the form of a ridge, a p-type GaInP intermediate layer 8, a p-type GaAs contact layer 9, and an n-type AlInP current blocking layer 10 that are formed on the substrate 1 by a MOCVD method. The active layer 4 may be, e.g., a GaInP/AlGaInP active layer having a multiple quantum well structure (with an oscillation wavelength of 650 nm). In a laser end face portion, the p-type contact layer 9 is removed.

An end face window structure region 11 where Zn is diffused into the layers located above the active layer 4, i.e., the p-type first cladding layer 5, the etching stop layer 6, the p-type second cladding layer 7, and the p-type intermediate layer 8 is formed in the laser end face portion.

In this structure, the end face window structure region 11 is formed by the diffusion of Zn that occurs due to a difference in Zn concentration present in the laser device. Therefore, from an optical viewpoint, the refractive index of a portion contributing to the laser oscillation is equivalent to or slightly different from that of the end face window structure region 11. Moreover, the current flowing through the end face portion can be suppressed as a result of increased resistance of the end face portion.

In general, when the window structure is formed by solid phase diffusion of Zn, the Zn concentration in the p-type cladding layers of the window region is about an order of magnitude greater than that of the gain portion contributing to the laser oscillation. Therefore, the refractive index of the window region varies with respect to the laser gain portion, and the resistance becomes low because of such a high impurity concentration. In contrast, the structure of this embodiment can suppress a rise in Zn concentration in the end face window structure region 11. Thus, it is possible to avoid reducing the resistance, so that the current flow into the end face portion can be suppressed. Moreover, since the Zn diffusion is less expanded in the resonator direction and the impurity concentration is low in the window region, the absorption of free carriers can be suppressed, resulting in a laser device with a smaller waveguide loss.

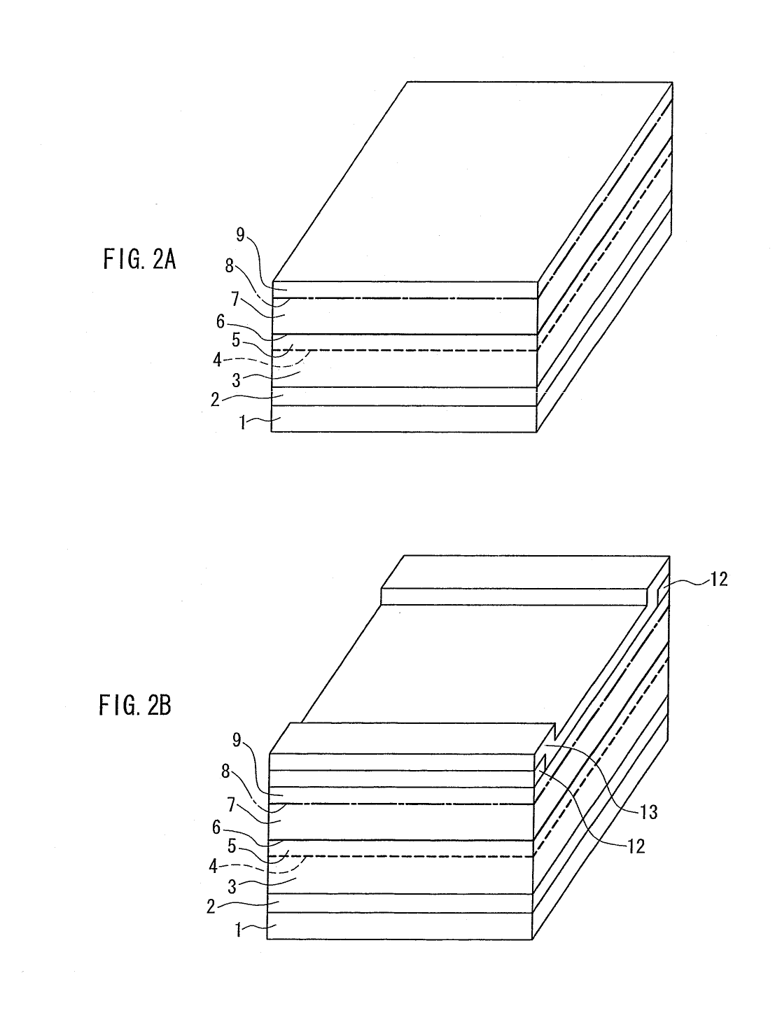

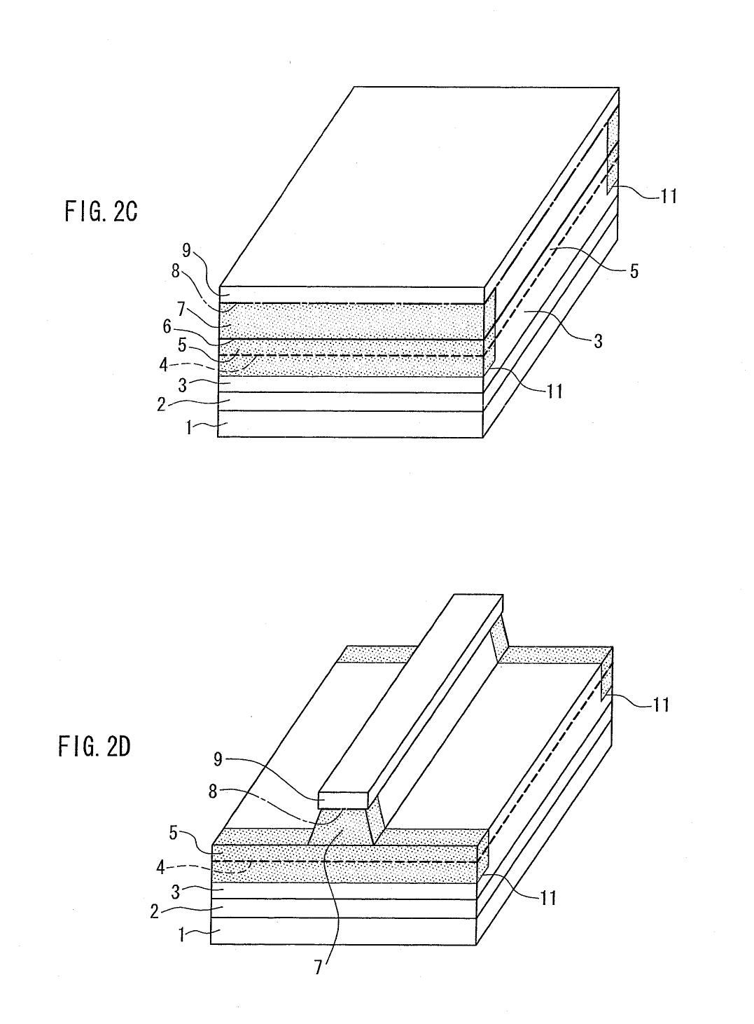

Next, a method for manufacturing a semiconductor laser device having the above structure will be described. FIGS. 2A to 2D are perspective views showing the processes of the manufacturing method in this embodiment.

As shown in FIG. 2A, first, the n-type buffer layer 2, the n-type cladding layer 3, the active layer 4, the p-type first cladding layer 5, the etching stop layer 6, the p-type second cladding layer 7, the p-type intermediate layer 8, and the p-type contact layer 9 are formed in this order on the n-type OFF substrate 1 by the MOCVD method.

In this embodiment, there are differences in Zn concentration among the p-type layers when they are formed. The Zn concentration of each layer is 7×10¹⁷ cm⁻³ for the p-type first cladding layer 5, 1×10^{18 cm}⁻³ for the p-type second cladding layer 7, and 9×10¹⁸ cm⁻³ for the p-type contact layer 9. The layers are doped with Zn so that the carrier concentration is increased from the active layer 4 toward the upper layers as mentioned above, by growing the layers using a source gas containing Zn.

Next, a Si film is deposited on the entire surface of the p-type contact layer 9 by using a sputtering apparatus (not shown). The Si film is patterned by photolithography and etching to leave a portion only 20 μm from each end face, as represented by the Si films 12 in FIG. 2B. The etching may be performed, e.g., by RIE (reactive ion etching) with a CF₄ gas. Subsequently, a SiO₂ film 13 is deposited on the entire surface by a CVD method.

Next, heat treatment is performed at 600° C. in an annealing furnace, so as to allow Zn that is present in the range of the p-type first cladding layer 5 to the p-type GaAs contact layer 9 formed on the active layer 4 to be diffused into the n-type cladding layer 3, as shown in FIG. 2C, which causes the active layer 4 to be changed to a mixed crystal, thereby providing the end face window structure region 11 at both end faces.

The thickness of the Si film 12 is set to, e.g., 100 nm so that the Si film 12 exerts a strong stress in the substrate 1 and does not peel off during the deposition of the SiO₂ film 13 used as a cap film. The SiO₂ film 13 functions as a cap film to prevent sublimation of P atoms or the like in annealing the laser gain portion. When the Si films 12 exerting a strong stress are disposed, a driving force is generated that diffuses Zn from the p-type layers in the corresponding region of each of the Si films 12 to the active layer 4 during annealing, and thus a window structure can be formed by disordering of the active layer 4.

Next, the SiO₂ film 13 and the Si films 12 disposed on the entire surface of the wafer are removed with chemicals such as hydrofluoric acid. To form a ridge, a SiO₂ film is formed as a mask of a stripe pattern by photolithography and dry etching (not shown).

As shown in FIG. 2D, the p-type contact layer 9, the p-type intermediate layer 8, and the p-type second cladding layer 7 are etched to the etching stop layer 6 by using the stripe-shaped SiO₂ film as a mask, thus forming a ridge. The etching may be performed, e.g., by a combination of dry etching using inductively coupled plasma or reactive ion plasma and wet etching.

Subsequently, a mask for etching the p-type contact layer 9 only in the Zn diffusion region of each end face portion is formed by photolithography (not shown), and the stripe-shaped SiO₂ film and the p-type contact layer 9 (GaAs layer) are etched. Thus, both end face portions of the p-type contact layer 9 are removed, as shown in FIGS. 1A and 1B. In this case, the etchant may be, e.g., a sulfuric acid-based etchant. Then, the mask for etching the p-type contact layer 9 is removed.

Next, as shown in FIG. 1A, the current blocking layer 10 is grown, followed by removal of the SiO₂ film on the ridge stripe.

As described above, the manufacturing method of this embodiment can form an end face window structure that has a small difference in Zn concentration between the window region of each end face and the gain portion.

Setting the carrier concentration in the p-type layers is important for the formation of the end face window structure. In this embodiment, the p-type first cladding layer 5, the etching stop layer 6, the p-type second cladding layer 7, the p-type intermediate layer 8, and the p-type contact layer 9 differ from one another in Zn carrier concentration. For example, the Zn carrier concentration is 7×10¹⁷ cm⁻³ for the p-type first cladding layer 5, 1×10^{18 cm}⁻³ for the p-type second cladding layer 7, and 9×10¹⁸ cm⁻³ for the p-type contact layer 9. That is, the Zn carrier concentration is set to be higher as it moves upward from the active layer.

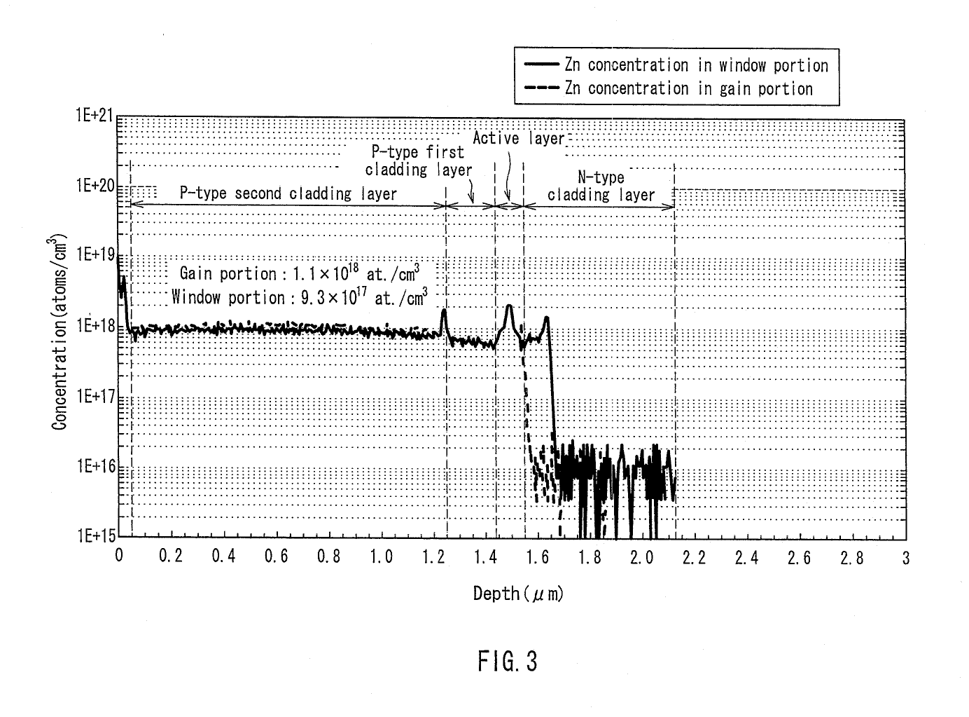

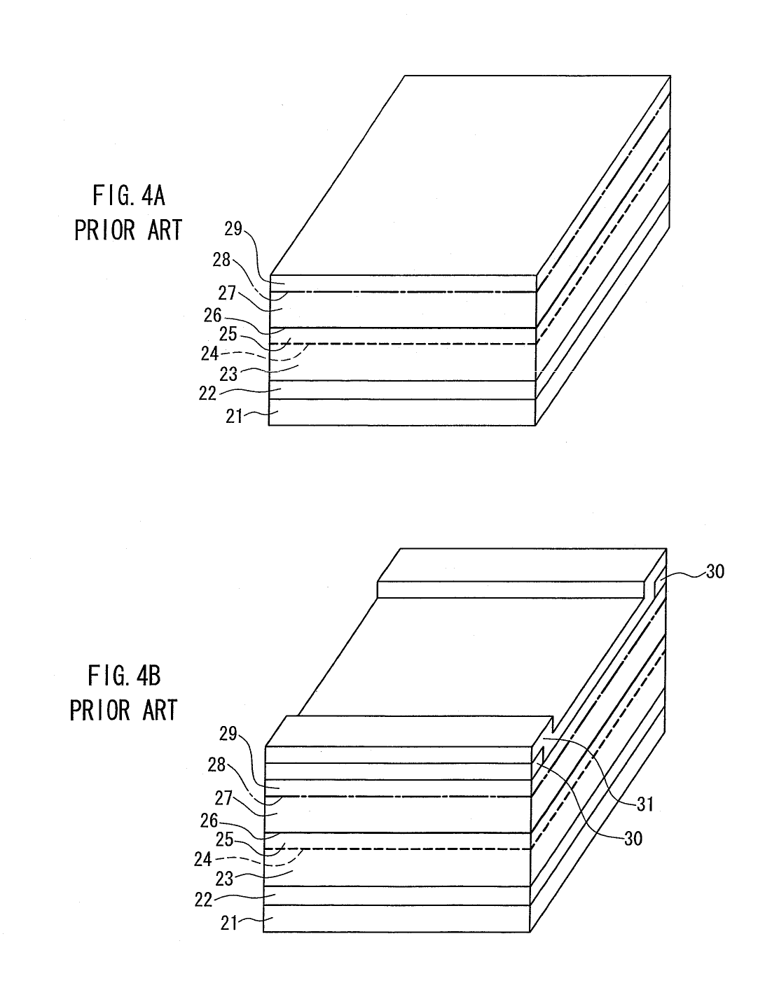

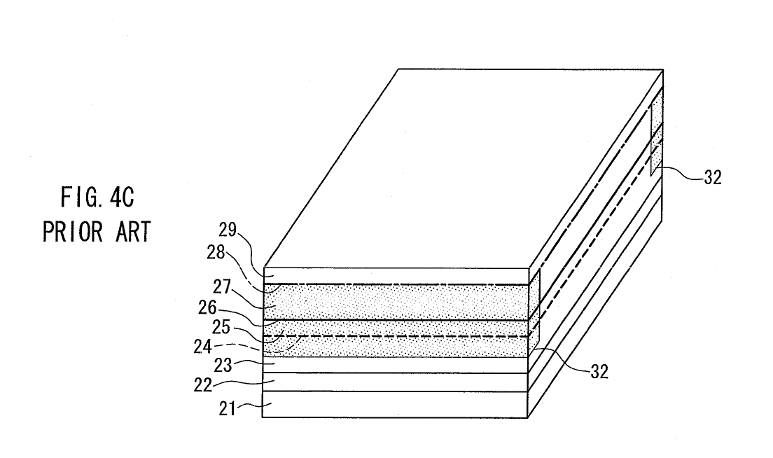

Therefore, when the Si films 12 are disposed on the p-type contact layer 9 and annealed, the diffusion occurs due to the stress applied to the p-type layers and the concentration gradient is balanced by annealing, as indicated by the SIMS profile (solid line) of Zn in FIG. 3. Consequently, Zn is diffused into the active layer 4 and part of the n-type cladding layer 3. This Zn diffusion allows the active layer 4 of each end face portion to be disordered.

In this embodiment, as shown in the SIMS profile of Zn in FIG. 3, the Zn concentration in the cladding layers of the window portion is about 2×10¹⁷ cm⁻³ lower than that of the cladding layers of the gain portion, and the window portion has a higher resistance.

The Zn concentration in the cladding layers needs to be set while considering reliability because Zn is diffused even in the gain portion by thermal hysteresis at the time of formation of the window structure and the subsequent crystal growth. When the carrier is Zn, it is desirable that the concentration is 1×10¹⁸ cm⁻³ or less in the p-type first cladding layer 5 ((AlₓGa₁₋ₓ)_{y}In_{1-y}P), 1.5×10¹⁸ cm⁻³ or less in the p-type second cladding layer 7 ((AlₓGa₁₋ₓ)_{y}In_{1-y}P), and 8×10¹⁸ to 5×10¹⁹ cm⁻³ in the p-type contact layer 9 (GaAs).

The annealing temperature is preferably 400 to 800° C. in view of the effect of Zn diffusion into the gain portion on reliability, the effect of an increase in the diffusion concentration of impurities on crystallinity degradation and reliability, and control of the shape and divergence angle of a laser beam resulting from the spread of impurities in the resonator direction of the gain portion.

Considering the influence of the above properties, it is desirable that the diffusion concentration of impurities into the active layer region of the end face portion is 1×10¹⁸ to 5×10¹⁸ cm⁻³.

Moreover, it is desirable that the spread of impurities in the resonator direction of the gain portion is adjusted within 15 μm.

To form a window structure available for high output, it is desirable that there is a concentration difference of 1×10¹⁷ cm⁻³ or more between at least the p-type first cladding layer 5 and the p-type second cladding layer 7.

Even if there is no carrier concentration difference, the Zn diffusion can occur by applying a stress.

Since a film exerting a high stress in the substrate can cause carrier diffusion, a dielectric film such as SiN or Ta₂O₃ or other films obtained by sputtering may be deposited as a source of diffusion force used for forming the window structure, while a film containing Si is desirable. Therefore, the source of diffusion force may be a single layer or multilayer film selected from Si, SiN, SiO₂, TiO₂, Ta₂O₅, NbO, hydrogenated amorphous Si or the like.

Although the above example uses Zn as a carrier of the second conductivity type, Mg or other impurities for the second conductivity type also can have a similar effect.

In the above example, the red laser has been described. However, the present invention is applicable to general compound semiconductor lasers that require a window structure such as an infrared laser or blue-purple laser.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A semiconductor laser device comprising:
a first conductivity type semiconductor substrate;
a first conductivity type cladding layer that is disposed on the semiconductor substrate;
an active layer that is disposed on the first conductivity type cladding layer and has a multiple quantum well structure;
a second conductivity type first cladding layer that is disposed on the active layer;
a second conductivity type second cladding layer that is disposed on the second conductivity type first cladding layer and forms a ridge waveguide extending in a resonator direction;
a second conductivity type contact layer that is disposed on the second conductivity type second cladding layer; and
an end face window structure in which impurities are diffused into an active layer region of an end face portion in the resonator direction, and thus a band gap is enlarged compared to a gain region that is a portion other than the end face portion,
wherein in the second conductivity type first and second cladding layers, an impurity concentration in the gain region is the same as or larger than that in a region of the end face window structure.

2. The semiconductor laser device according to claim 1, wherein carriers in the second conductivity type first and second cladding layers and impurities in the end face window structure are the same element.

3. The semiconductor laser device according to claim 2, wherein the carriers in the second conductivity type first and second cladding layers are Zn or Mg.

4. The semiconductor laser device according to claim 1, wherein a carrier concentration in each of the second conductivity type layers in the gain region is set to satisfy a relationship of (concentration in the contact layer)≧(concentration in the second cladding layer)≧(concentration in the first cladding layer).

5. The semiconductor laser device according to claim 4, wherein the second conductivity type contact layer is formed of a single layer film or multilayer film with a carrier concentration of 8×10¹⁸ to 5×10¹⁹ cm⁻³.

6. The semiconductor laser device according to claim 4, wherein the second conductivity type second cladding layer has a carrier concentration of 1.5×10¹⁸ cm⁻³ or less.

7. The semiconductor laser device according to claim 4, wherein the second conductivity type first cladding layer has a carrier concentration of 1×10¹⁸ cm⁻³ or less.

8. The semiconductor laser device according to claim 1, wherein second conductivity type impurities are piled up in a concentration of 1×10¹⁸ to 5×10¹⁸ cm⁻³ in the active layer of the end face window structure region.

9. The semiconductor laser device according to claim 1, wherein second conductivity type impurities are diffused into the first conductivity type cladding layer in the end face window structure region.

10. The semiconductor laser device according to claim 9, wherein a depth of diffusion of the impurities into the first conductivity type cladding layer in the end face window structure region is within 2 μm.

11. A method for manufacturing a semiconductor laser device comprising:
performing crystal growth of a first conductivity type cladding layer, an active layer, a second conductivity type first cladding layer, a second conductivity type second cladding layer, and a second conductivity type contact layer in this order on a semiconductor substrate;
depositing a source of diffusion force that includes no second conductivity type impurity on only an end face portion in a resonator direction;
performing annealing so as to cause a stress generated by the source of diffusion force to be applied to the layers, allowing impurities inside the layers to be diffused to form an end face window structure;
forming the second conductivity type second cladding layer into a ridge waveguide extending in the resonator direction;
removing the second conductivity type contact layer in a region of the end face window structure; and
forming a first conductivity type blocking layer on sides of the second conductivity type second cladding layer in the form of a ridge waveguide and also regions on both sides of the second cladding layer.

12. The method according to claim 11, wherein the formation of the end face window structure by impurity diffusion in the end face portion is performed by extruding the impurities present in the second conductivity type second cladding layer and the second conductivity type contact layer from above so that the impurities are diffused into the active layer.

13. The method according to claim 11, wherein the source of diffusion force formed in the end face portion is a single layer or multilayer film selected from any of Si, SiN, SiO₂, TiO₂, Ta₂O₅, NbO, and hydrogenated amorphous Si.

14. The method according to claim 13, wherein a diffusion concentration of impurities diffused by action of the source of diffusion force is 1×10¹⁷ cm⁻³ or more.

15. The method according to claim 11, wherein the formation of the end face window structure by impurity diffusion in the end face portion is performed at an annealing temperature of 400 to 800° C.

16. The method according to claim 11, wherein the formation of the end face window structure by impurity diffusion in the end face portion is performed so that the impurity diffusion in the resonator direction is controlled within 15 μm with respect to a width of the source of diffusion force.
